(19) United States
(12) Patent Application Publication
(10) Pub. No.: US 2025/0293657 A1
(43) Pub. Date: Sep. 18, 2025

(54) FILTER DEVICE

(71) Applicant: TDK Corporation, Tokyo (JP)

(72) Inventors: Yuta ASHIDA, Tokyo (JP); Keigo SHIBUYA, Tokyo (JP); Takuya SATO, Tokyo (JP); Masato YAMAGUCHI, Tokyo (JP); Tetsu KAWAKAMI, Tokyo (JP); Ryoko MATSUBA, Tokyo (JP)

(73) Assignee: TDK Corporation, Tokyo (JP)

(21) Appl. No.: 19/066,187

(22) Filed: Feb. 28, 2025

(30) Foreign Application Priority Data
Mar. 15, 2024 (JP) 2024-041426

(51) Int. Cl. H03H 7/01; H03H 9/46

(52) U.S. Cl. CPC H03H 7/0169; H03H 7/1708; H03H 7/1783; H03H 9/46

(57) ABSTRACT

The filter device includes: a first body including an inductor and a capacitor; a second body that is mounted on the first body and that includes an acoustic wave element; a filter circuit including an inductor, a capacitor, and an acoustic wave element; a first capacitor; and a second capacitor. The first body further includes a first signal terminal and a second signal terminal. The filter circuit is, in a circuit configuration, provided between the first signal terminal and the second signal terminal. The first capacitor is provided on a first path connecting the first signal terminal and the filter circuit. The second capacitor is provided on a second path connecting the second signal terminal and the filter circuit.

### CROSS-REFERENCE TO RELATED APPLICATION

This application claims the benefit of Japanese Priority Patent Application No. 2024-041426 filed on Mar. 15, 2024, the entire contents of which are incorporated herein by reference.

### BACKGROUND

The disclosure relates to a filter device including a body and parts mounted on the body.

A filter such as a low-pass filter, a high-pass filter, or a band-pass filter includes a plurality of resonators. As the resonators used for such a filter, for example, an LC resonator including an inductor and a capacitor and an acoustic wave resonator including an acoustic wave element are known. The acoustic wave element is an element using an acoustic wave. Examples of the acoustic wave element include a surface acoustic wave element using a surface acoustic wave and a bulk acoustic wave element using a bulk acoustic wave.

For example, WO 2009/136472 discloses an acoustic wave filter device including first and second acoustic wave filter chips implemented on a laminated substrate. In the acoustic wave filter device, the first acoustic wave filter chip is provided between an input terminal and a reception terminal and the second acoustic wave filter chip is provided between an input terminal and a transmission terminal.

In a filter device using an acoustic wave element, on the front stage side and back stage side of the acoustic wave element, a plurality of elements may be provided. Here, it is considered that a filter device provided with a filter unit including an acoustic wave element receives, as an interference wave, a signal in a frequency lower than a passband of the filter unit. When the interference wave is input into the plurality of elements on the front stage side and back stage side of the filter unit, besides the interference wave, the plurality of elements output harmonics in a frequency higher than that of the interference wave. In a case where the frequency of such harmonics is within the passband of the filter unit, the harmonics are superimposed as noise on a signal to be extracted by the filter device.

In general, a filter device includes a plurality of terminals. The plurality of terminals includes a plurality of signal terminals used for input or output of signals and at least one ground terminal connected to the ground. When the plurality of terminals are electrically connected to each other, a current larger than usual may flow between the plurality of terminals due to electrostatic discharge. In particular, in a filter device using an acoustic wave element, with the acoustic wave element provided between two terminals electrically connected to each other, the acoustic wave element may be damaged due to electrostatic discharge.

Meanwhile, in a filter device using an acoustic wave element, as the acoustic wave filter device disclosed in WO 2009/136472, a first part including an acoustic wave element and a second part including another component are included. The first part is mounted on the second part. The issue described above applies, not only to a case that the first part includes an acoustic wave element but also to a case that the first part includes any element possible to cause damage by static electricity.

### SUMMARY

A filter device according to one embodiment of the disclosure includes: a first body including a first element; a second body that is mounted on the first body and that includes a second element; a filter circuit including the first element and the second element; a first capacitor; and a second capacitor. The first body further includes a first signal terminal and a second signal terminal. The filter circuit is, in a circuit configuration, provided between the first signal terminal and the second signal terminal. The first capacitor is provided on a first path connecting the first signal terminal and the filter circuit. The second capacitor is provided on a second path connecting the second signal terminal and the filter circuit.

Other and further objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a circuit diagram showing a circuit configuration of a filter device according to an example embodiment of the disclosure.

FIG. 2 is a perspective view showing the filter device according to the example embodiment of the disclosure.

FIG. 3 is a perspective view showing a first body of the filter device according to the example embodiment of the disclosure.

FIG. 4 is a perspective view showing the first body of the filter device according to the example embodiment of the disclosure.

FIGS. 5A to 5C are explanatory diagrams showing respective patterned surfaces of first to third dielectric layers in the first body shown in FIGS. 2 to 4.

FIGS. 6A to 6C are explanatory diagrams showing respective patterned surfaces of fourth to sixth dielectric layers in the first body shown in FIGS. 2 to 4.

FIG. 7A is an explanatory diagram showing a patterned surface of each of seventh to thirteenth dielectric layers in the first body shown in FIGS. 2 to 4.

FIGS. 7B and 7C are explanatory diagrams showing respective patterned surfaces of fourteenth and fifteenth dielectric layers in the first body shown in FIGS. 2 to 4.

FIGS. 8A to 8C are explanatory diagrams showing respective patterned surfaces of sixteenth to eighteenth dielectric layers in the first body shown in FIGS. 2 to 4.

FIG. 9 is an explanatory diagram showing an electrode formation surface of the eighteenth dielectric layer in the first body shown in FIGS. 2 to 4.

FIG. 10 is a perspective view showing inside of the first body according to the example embodiment of the disclosure.

### DETAILED DESCRIPTION

An object of the disclosure is to provide a filter device that enables reliability to be enhanced.

In the following, some example embodiments and modification examples of the disclosure will be described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

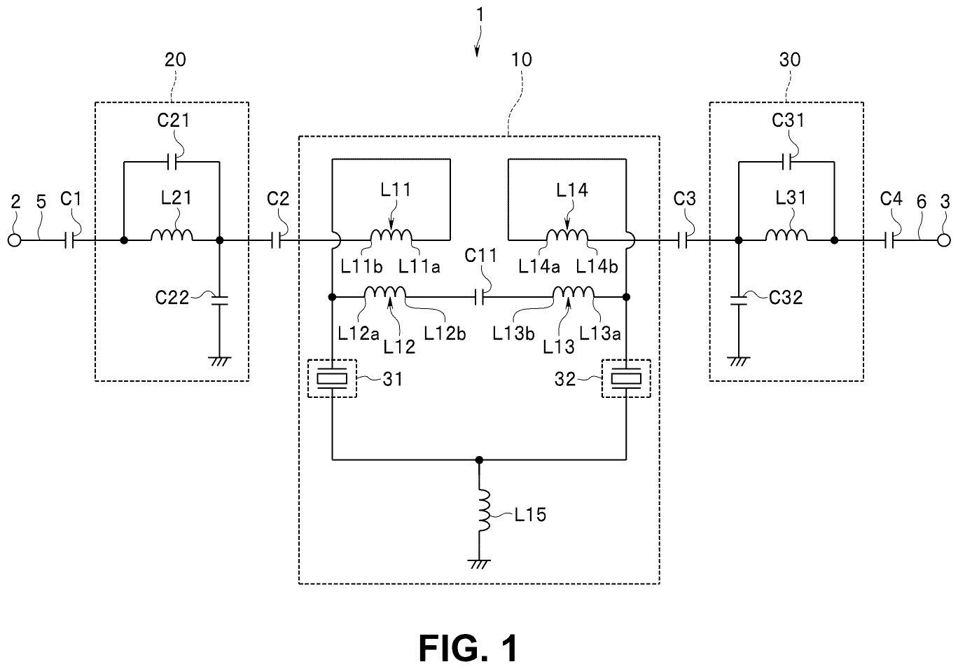

First, with reference to FIG. 1, a schematic configuration of a filter device 1 according to an example embodiment of the disclosure will be described. The filter device 1 according to the example embodiment includes a first signal terminal 2, a second signal terminal 3, and a filter circuit 10 provided between the first signal terminal 2 and the second signal terminal 3 in a circuit configuration. In particular in the example embodiment, the filter circuit 10 is included in a high-pass filter. Note that, in the present application, the expression “in a circuit configuration” is used to describe an arrangement in a circuit diagram, not in a physical configuration.

Each of the first and second signal terminals 2 and 3 is a signal terminal for input or output of a signal. Specifically, when a signal is input to the first signal terminal 2, a signal is output from the second signal terminal 3. When a signal is input to the second signal terminal 3, a signal is output from the first signal terminal 2.

The filter device 1 further includes a first path 5 that is a path connecting the first signal terminal 2 and the filter circuit 10 and that reaches the filter circuit 10 from the first signal terminal 2, a second path 6 that is a path connecting the second signal terminal 3 and the filter circuit 10 and that reaches the filter circuit 10 from the second signal terminal 3, a first low-pass filter 20 provided on the first path 5, and a second low-pass filter 30 provided on the second path 6. In particular in the example embodiment, the filter circuit 10 and the first and second low-pass filters 20 and 30 are connected in series, in the order of the first low-pass filter 20, the filter circuit 10 (high-pass filter), and the second low-pass filter 30, from the first signal terminal 2 toward the second signal terminal 3.

The filter device 1 further includes capacitors C1 and C2 provided on the first path 5 and capacitors C3 and C4 provided on the second path 6. The capacitor C1 is, in the circuit configuration, provided between the first signal terminal 2 and the first low-pass filter 20. The capacitor C2 is, in the circuit configuration, provided between the first low-pass filter 20 and the filter circuit 10. The capacitor C3 is, in the circuit configuration, provided between the filter circuit 10 and the second low-pass filter 30. The capacitor C4 is, in the circuit configuration, provided between the second low-pass filter 30 and the second signal terminal 3.

In the example embodiment, the high-pass filter includes the filter circuit 10 and the capacitors C2 and C3. The filter device 1 is a band-pass filter including the filter circuit 10, the first and second low-pass filters 20 and 30, and the capacitors C2 and C3. The filter device 1 is configured to cause a signal of a frequency in a predetermined passband to pass selectively.

Now, with reference to FIG. 1, an example of a circuit configuration of each of the filter circuit 10, the first low-pass filter 20, and the second low-pass filter 30 will be described. First, the circuit configuration of the filter circuit 10 will be described. The filter circuit 10 includes inductors L11, L12, L13, and L14 and a capacitor C11. Each of the inductors L11 to L14 includes a first end and a second end located opposite to each other. Hereinafter, the first end and second end of the inductor L11 are respectively denoted by reference numerals L11a and L11b, the first end and second end of the inductor L12 are respectively denoted by reference numerals L12a and L12b, the first end and second end of the inductor L13 are respectively denoted by reference numerals L13a and L13b, and the first end and second end of the inductor L14 are respectively denoted by reference numerals L14a and L14b.

The first end L11a of the inductor L11 and the first end L12a of the inductor L12 are connected to each other. The second end L11b of the inductor L11 is connected to the capacitor C2. The second end L12b of the inductor L12 is connected to one end of the capacitor C11.

The first end L13a of the inductor L13 and the first end L14a of the inductor L14 are connected to each other. The second end L13b of the inductor L13 is connected to the other end of the capacitor C11. The second end L14b of the inductor L14 is connected to the capacitor C3.

The filter circuit 10 further includes acoustic wave elements 31 and 32 and an inductor L15. Each of the acoustic wave elements 31 and 32 may be a bulk acoustic wave element or may be a surface acoustic wave element, for example. One end of the acoustic wave element 31 is connected to the first end L11a of the inductor L11 and the first end L12a of the inductor L12. One end of the acoustic wave element 32 is connected to the first end L13a of the inductor L13 and the first end L14a of the inductor L14. The other end of each of the acoustic wave elements 31 and 32 is connected to one end of the inductor L15. The other end of the inductor L15 is connected to the ground.

The inductor L11 is, in the circuit configuration, provided between the first signal terminal 2 and the acoustic wave element 31. The inductor L12 is, in the circuit configuration, provided between the second signal terminal 3 and the acoustic wave element 31. The inductor L13 is, in the circuit configuration, provided between the first signal terminal 2 and the acoustic wave element 32. The inductor L14 is, in the circuit configuration, provided between the second signal terminal 3 and the acoustic wave element 32.

Each of the acoustic wave elements 31 and 32 is electrically connected to the ground via the inductor L15. Note that, in the present application, the expression “electrically connected to” includes a case of being electrically connected via a metal conductor (including an inductor), but not a case of being connected via a capacitor. Between the acoustic wave element 31 and the first signal terminal 2, the capacitors C1 and C2 are interposed, and thus the acoustic wave element 31 is not electrically connected to the first signal terminal 2. Between the acoustic wave element 31 and the second signal terminal 3, the capacitors C3, C4, and C11 are interposed, and thus the acoustic wave element 31 is not electrically connected to the second signal terminal 3. Between the acoustic wave element 32 and the first signal terminal 2, the capacitors C1, C2, and C11 are interposed, and thus the acoustic wave element 32 is not electrically connected to the first signal terminal 2. Between the acoustic wave element 32 and the second signal terminal 3, the capacitors C3 and C4 are interposed, and thus the acoustic wave element 32 is not electrically connected to the second signal terminal 3.

The inductors L11 to L15, the capacitor C11, and the acoustic wave elements 31 and 32 are included in the high-pass filter.

Next, the circuit configuration of the first low-pass filter 20 will be described. The first low-pass filter 20 includes an inductor L21 and capacitors C21 and C22. One end of the inductor L21 is connected to the capacitor C1. The other end of the inductor L21 is connected to the capacitor C2.

The capacitor C21 is connected in parallel to the inductor L21. One end of the capacitor C22 is connected to the other end of the inductor L21. The other end of the capacitor C22 is connected to the ground.

Next, the circuit configuration of the second low-pass filter 30 will be described. The second low-pass filter 30 includes an inductor L31 and capacitors C31 and C32. One end of the inductor L31 is connected to the capacitor C3. The other end of the inductor L31 is connected to the capacitor C4.

The capacitor C31 is connected in parallel to the inductor L31. One end of the capacitor C32 is connected to the one end of the inductor L31. The other end of the capacitor C32 is connected to the ground.

Next, a connection relation of the capacitors C1 to C4 will be described. One end of the capacitor C1 is connected to the first signal terminal 2. The other end of the capacitor C1 is connected to the one end of the inductor L21. One end of the capacitor C2 is connected to the other end of the inductor L21. The other end of the capacitor C2 is connected to the second end L11b of the inductor L11.

One end of the capacitor C3 is connected to the second end L14b of the inductor L14. The other end of the capacitor C3 is connected to the one end of the inductor L31. One end of the capacitor C4 is connected to the other end of the inductor L31. The other end of the capacitor C4 is connected to the second signal terminal 3.

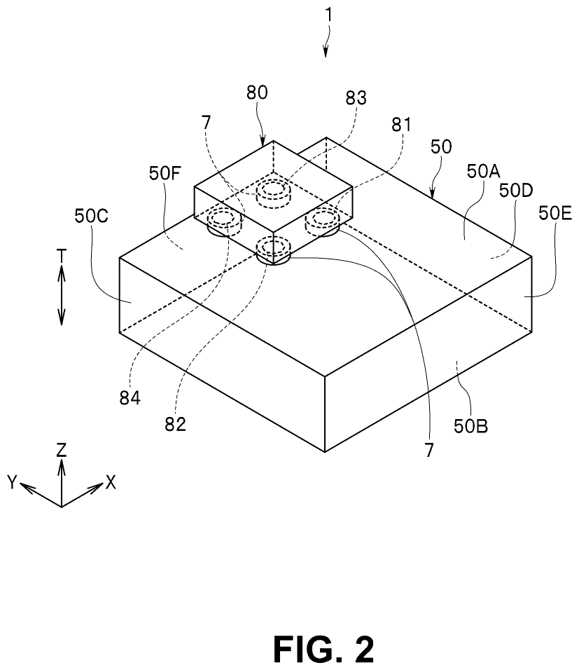

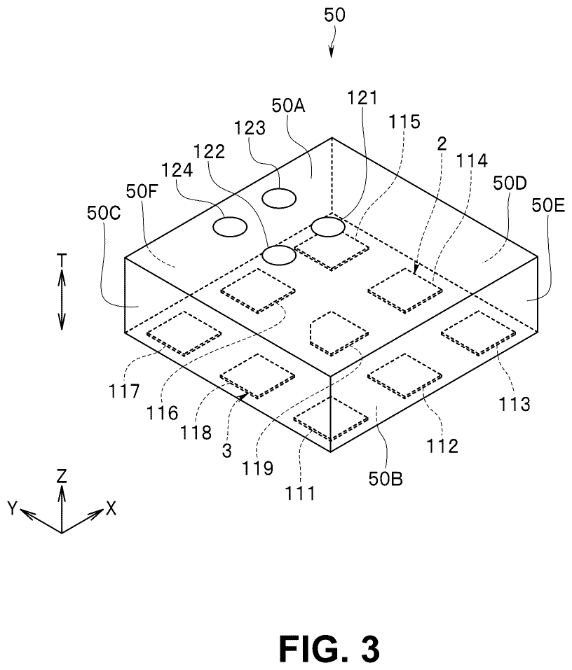

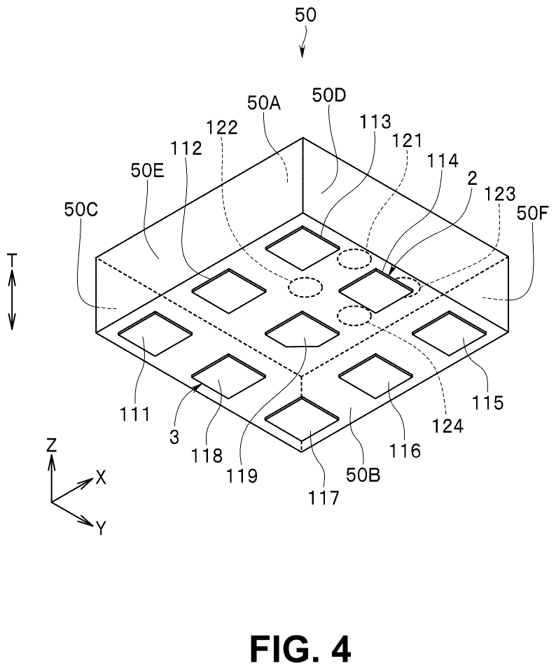

Next, with reference to FIGS. 2 to 4, other configurations of the filter device 1 will be described. FIG. 2 is a perspective view showing the filter device 1. FIGS. 3 and 4 are each a perspective view showing a first body of the filter device 1.

The filter device 1 according to the example embodiment includes a first body 50 and a second body 80 mounted on the first body 50. The first body 50 includes a stack including a plurality of dielectric layers stacked and a plurality of conductors (a plurality of conductor layers and a plurality of through holes). Each of the plurality of dielectric layers includes a dielectric material. As such a dielectric material, for example, a low temperature co-fired ceramic (LTCC) is used.

The first body 50 includes at least one first element. The second body 80 includes at least one second element. The filter device 1 is provided with a circuit including the at least one first element and the at least one second element. In the example embodiment, the first body 50 includes, as the at least one first element, the inductors L11 to L15 and the capacitor C11 shown in FIG. 1. The second body 80 includes, as the at least one second element, the acoustic wave elements 31 and 32 shown in FIG. 1. The filter device 1 is provided with, as the circuit described above, the filter circuit 10 including the inductors L11 to L15, the capacitor C11, and the acoustic wave elements 31 and 32.

The first body 50 further includes the inductors L21 and L31 and the capacitors C1 to C4, C21, C22, C31, and C32 shown in FIG. 1. The inductors L11 to L15, L21, and L31 and the capacitors C1 to C4, C11, C21, C22, C31, and C32 are provided inside the first body 50 being the stack and are configured using the plurality of dielectric layers and the plurality of conductors. The acoustic wave elements 31 and 32 are mounted on the first body 50 being the stack.

The first body 50 has a first surface 50A and a second surface 50B located at both ends in a stacking direction T of the plurality of dielectric layers, and four side surfaces 50C to 50F connecting the first surface 50A and the second surface 50B. The side surfaces 50C and 50D are opposite to each other. The side surfaces 50E and 50F are opposite to each other. The side surfaces 50C to 50F are perpendicular to the first surface 50A and the second surface 50B.

Here, X, Y, and Z directions are defined as shown in FIGS. 2 to 4. The X, Y, and Z directions are orthogonal to one another. In the example embodiment, a direction parallel to the stacking direction T is referred to as the Z direction. The opposite directions to the X, Y, and Z directions are defined as −X, −Y, and −Z directions, respectively. The expression “when seen in a predetermined direction (for example, Z direction)” means that an intended object is seen from a position at a distance in the predetermined direction or a direction parallel to the predetermined direction.

As shown in FIGS. 2 to 4, the first surface 50A is located at the end of the first body 50 in the Z direction. The first surface 50A is a top surface of the first body 50, which is a surface for the second body 80 to be mounted on. The second surface 50B is located at the end of the first body 50 in the −Z direction. The second surface 50B is a bottom surface of the first body 50. FIG. 3 shows the first body 50 when seen from the first surface 50A side. FIG. 4 shows the first body 50 when seen from the second surface 50B side.

The side surface 50C is located at the end of the first body 50 in the −X direction. The side surface 50D is located at the end of the first body 50 in the X direction. The side surface 50E is located at the end of the first body 50 in the −Y direction. The side surface 50F is located at the end of the first body 50 in the Y direction.

The first body 50 further includes a plurality of electrodes 111, 112, 113, 114, 115, 116, 117, 118, and 119 provided on the second surface 50B of the first body 50. The electrodes 111, 112, and 113 are arranged in this order in the X direction at positions closer to the side surface 50E than the side surface 50F. The electrodes 115, 116, and 117 are arranged in this order in the −X direction at positions closer to the side surface 50F than the side surface 50E.

The electrode 114 is disposed between the electrode 113 and electrode 115. The electrode 118 is disposed between the electrode 111 and electrode 117. The electrode 119 is disposed between the electrode 112 and electrode 116. The electrode 119 is disposed substantially at the center of the second surface 50B.

The electrode 114 corresponds to the first signal terminal 2. The electrode 118 corresponds to the second signal terminal 3. Thus, the first and second signal terminals 2 and 3 are provided on the second surface 50B of the first body 50. Each of the electrodes 111, 112, 113, 115, 116, 117, and 119 is connected to the ground.

The first body 50 further includes a plurality of electrodes 121, 122, 123, and 124 provided on the first surface 50A of the first body 50. The electrodes 121 and 122 are arranged in this order in the −X direction at positions closer to the side surface 50F than the side surface 50E. The electrodes 123 and 124, at positions beyond the electrodes 121 and 122 in the Y direction, are arranged in this order in the −X direction.

The second body 80 further includes four electrodes 81, 82, 83, and 84. In a state where the second body 80 is mounted on the first body 50, the four electrodes 81 to 84 are respectively opposed to the electrodes 121 to 124 of the first body 50. The four electrodes 81 to 84 are physically connected to the electrodes 121 to 124 with solder bumps 7, for example.

The filter device 1 further includes a seal (not illustrated) sealing the second body 80. The seal covers a periphery of the second body 80 and at least a part of the first surface 50A of the first body 50. The seal may further cover the side surfaces 50C to 50F of the first body 50. The seal is formed of resin, for example.

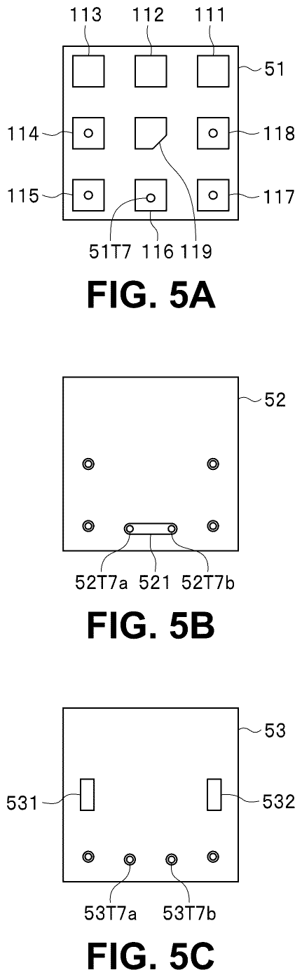

Next, with reference to FIGS. 5A to 9, an example of the plurality of dielectric layers, the plurality of conductor layers, and the plurality of through holes included in the first body 50 will be described. In this example, the first body 50 includes eighteen dielectric layers stacked. Hereinafter, the eighteen dielectric layers are referred to as first to eighteenth dielectric layers in the order from bottom to top. The first to eighteenth dielectric layers are denoted by reference numerals 51 to 68, respectively.

In FIGS. 5A to 8C, each circle represents a through hole. The dielectric layers 51 to 68 each include a plurality of through holes formed. The plurality of through holes are each formed by filling a hole intended for a through hole with a conductive paste. Each of the plurality of through holes is connected to an electrode, a conductor layer, or another through hole.

In FIGS. 5A to 8C, a plurality of specific through holes out of the plurality of through holes are denoted by reference numerals. A connection relation of each of the plurality of specific through holes and an electrode, a conductor layer, or another through hole is described as a connection relation in a state where the first to eighteenth dielectric layers 51 to 68 are stacked.

FIG. 5A shows a patterned surface of the first dielectric layer 51. The patterned surface of the dielectric layer 51 includes the electrodes 111 to 119 formed. In FIG. 5A, a through hole denoted by a reference numeral 51T7 is connected to the electrode 116. Note that, in the following description, the through hole denoted by the reference numeral 51T7 is simply referred to as a through hole 51T7. Through holes denoted by reference numerals other than the through hole 51T7 are also indicated in a manner similar to the through hole 51T7.

FIG. 5B shows a patterned surface of the second dielectric layer 52. The patterned surface of the dielectric layer 52 includes a conductor layer 521 formed. The through hole 51T7 and through holes 52T7a and 52T7b shown in FIG. 5B are connected to the conductor layer 521.

FIG. 5C shows a patterned surface of the third dielectric layer 53. The patterned surface of the dielectric layer 53 includes conductor layers 531 and 532 formed. The through holes 52T7a and 52T7b are respectively connected to through holes 53T7a and 53T7b shown in FIG. 5C.

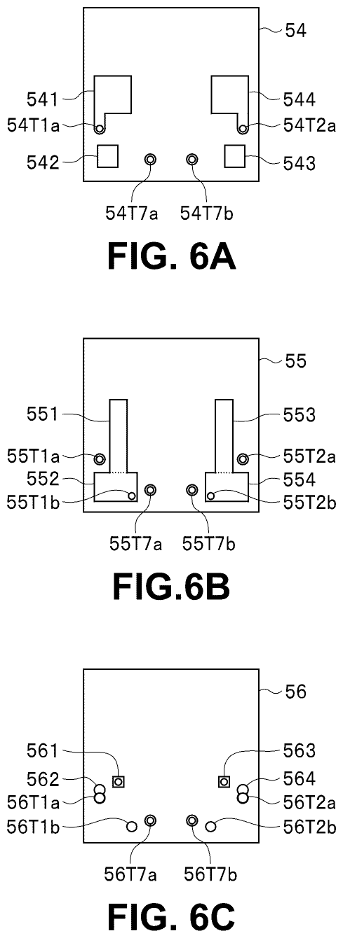

FIG. 6A shows a patterned surface of the fourth dielectric layer 54. The patterned surface of the dielectric layer 54 includes conductor layers 541, 542, 543, and 544 formed. Through holes 54T1a and 54T2a shown in FIG. 6A are respectively connected to the conductor layer 541 and 544. The through holes 53T7a and 53T7b are respectively connected to through holes 54T7a and 54T7b shown in FIG. 6A.

FIG. 6B shows a patterned surface of the fifth dielectric layer 55. The patterned surface of the dielectric layer 55 includes conductor layers 551, 552, 553, and 554 formed. The conductor layer 551 is connected to the conductor layer 552. The conductor layer 553 is connected to the conductor layer 554. In FIG. 6B, the boundary between the conductor layer 551 and the conductor layer 552 and the boundary between the conductor layer 553 and the conductor layer 554 are indicated by dotted lines.

Through holes 55T1b and 55T2b shown in FIG. 6B are respectively connected to the conductor layers 552 and 554. The through holes 54T1a, 54T2a, 54T7a, and 54T7b are respectively connected to through holes 55T1a, 55T2a, 55T7a, and 55T7b shown in FIG. 6B.

FIG. 6C shows a patterned surface of the sixth dielectric layer 56. The patterned surface of the dielectric layer 56 includes conductor layers 561, 562, 563, and 564 formed. The through hole 55T1a and a through hole 56T1a shown in FIG. 6C are connected to the conductor layer 562. The through hole 55T2a and a through hole 56T2a shown in FIG. 6C are connected to the conductor layer 564. The through holes 55T1b, 55T2b, 55T7a, and 55T7b are respectively connected to through holes 56T1b, 56T2b, 56T7a, and 56T7b shown in FIG. 6C.

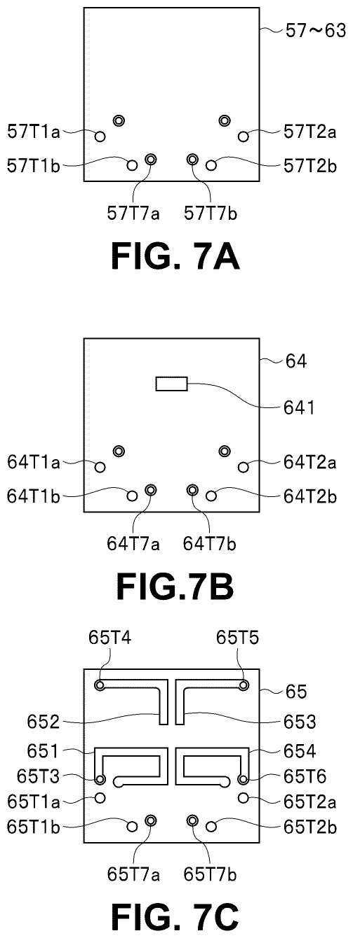

FIG. 7A shows a patterned surface of each of the seventh to thirteenth dielectric layers 57 to 63. The through holes 56T1a, 56T1b, 56T2a, 56T2b, 56T7a, and 56T7b are respectively connected to through holes 57T1a, 57T1b, 57T2a, 57T2b, 57T7a, and 57T7b formed in the dielectric layer 57. In the dielectric layers 57 to 63, every vertically adjacent through holes denoted by the same reference numeral are connected to each other.

FIG. 7B shows a patterned surface of the fourteenth dielectric layer 64. The patterned surface of the dielectric layer 64 includes a conductor layer 641 formed. The through holes 57T1a, 57T1b, 57T2a, 57T2b, 57T7a, and 57T7b formed in the dielectric layer 63 are respectively connected to through holes 64T1a, 64T1b, 64T2a, 64T2b, 64T7a, and 64T7b shown in FIG. 7B.

FIG. 7C shows a patterned surface of the fifteenth dielectric layer 65. The patterned surface of the dielectric layer 65 includes inductor conductor layers 651, 652, 653, and 654 formed. The conductor layer 651 includes a first end and a second end located opposite to each other in the longitudinal direction of the conductor layer 651. A through hole 65T3 shown in FIG. 7C is connected to a portion near the first end of the conductor layer 651. The conductor layer 652 includes a first end and a second end located opposite to each other in the longitudinal direction of the conductor layer 652. A through hole 65T4 shown in FIG. 7C is connected to a portion near the first end of the conductor layer 652.

The conductor layer 653 includes a first end and a second end located opposite to each other in the longitudinal direction of the conductor layer 653. A through hole 65T5 shown in FIG. 7C is connected to a portion near the first end of the conductor layer 653. The conductor layer 654 includes a first end and a second end located opposite to each other in the longitudinal direction of the conductor layer 654. A through hole 65T6 shown in FIG. 7C is connected to a portion near the first end of the conductor layer 654.

The through holes 64T1a, 64T1b, 64T2a, 64T2b, 64T7a, and 64T7b are respectively connected to through holes 65T1a, 65T1b, 65T2a, 65T2b, 65T7a, and 65T7b shown in FIG. 7C.

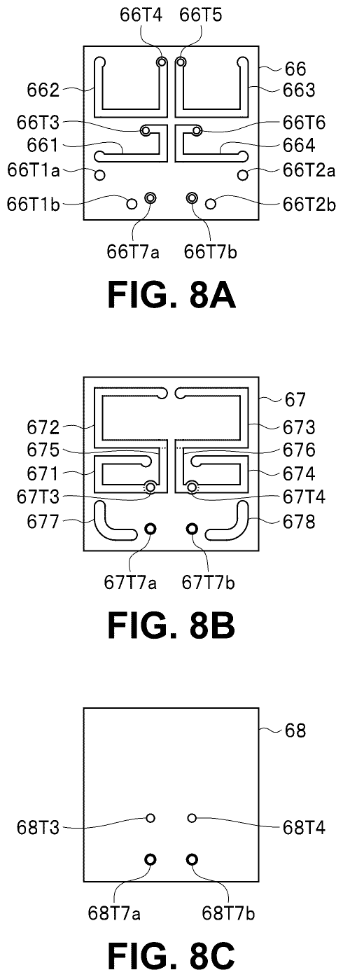

FIG. 8A shows a patterned surface of the sixteenth dielectric layer 66. The patterned surface of the dielectric layer 66 includes inductor conductor layers 661, 662, 663, and 664 formed. The conductor layer 661 includes a first end and a second end located opposite to each other in the longitudinal direction of the conductor layer 661. A through hole 66T3 shown in FIG. 8A is connected to a portion near the first end of the conductor layer 661. The through hole 65T3 is connected to a portion near the second end of the conductor layer 661. The conductor layer 662 includes a first end and a second end located opposite to each other in the longitudinal direction of the conductor layer 662. A through hole 66T4 shown in FIG. 8A is connected to a portion near the first end of the conductor layer 662. The through hole 65T4 is connected to a portion near the second end of the conductor layer 662.

The conductor layer 663 includes a first end and a second end located opposite to each other in the longitudinal direction of the conductor layer 663. A through hole 66T5 shown in FIG. 8A is connected to a portion near the first end of the conductor layer 663. The through hole 65T5 is connected to a portion near the second end of the conductor layer 663. The conductor layer 664 includes a first end and a second end located opposite to each other in the longitudinal direction of the conductor layer 664. A through hole 66T6 shown in FIG. 8A is connected to a portion near the first end of the conductor layer 664. The through hole 65T6 is connected to a portion near the second end of the conductor layer 664.

The through holes 65T1a, 65T1b, 65T2a, 65T2b, 65T7a, and 65T7b are respectively connected to through holes 66T1a, 66T1b, 66T2a, 66T2b, 66T7a, and 66T7b shown in FIG. 8A.

FIG. 8B shows a patterned surface of the seventeenth dielectric layer 67. The patterned surface of the dielectric layer 67 includes inductor conductor layers 671, 672, 673, 674, 677, and 678 and conductor layers 675 and 676 formed.

The conductor layer 671 includes a first end and a second end located opposite to each other in the longitudinal direction of the conductor layer 671. The conductor layer 672 includes a first end and a second end located opposite to each other in the longitudinal direction of the conductor layer 672. The first end of the conductor layer 671 and the first end of the conductor layer 672 are connected to the conductor layer 675. In FIG. 8B, the boundary between the conductor layer 671 and the conductor layer 675 and the boundary between the conductor layer 672 and the conductor layer 675 are indicated by dotted lines. A through hole 67T3 shown in FIG. 8B is connected to the conductor layer 675.

The through hole 66T3 is connected to a portion near the second end of the conductor layer 671. The through hole 66T4 is connected to a portion near the second end of the conductor layer 672.

The conductor layer 673 includes a first end and a second end located opposite to each other in the longitudinal direction of the conductor layer 673. The conductor layer 674 includes a first end and a second end located opposite to each other in the longitudinal direction of the conductor layer 674. The first end of the conductor layer 673 and the first end of the conductor layer 674 are connected to the conductor layer 676. In FIG. 8B, the boundary between the conductor layer 673 and the conductor layer 676 and the boundary between the conductor layer 674 and the conductor layer 676 are indicated by dotted lines. A through hole 67T4 shown in FIG. 8B is connected to the conductor layer 676.

The through hole 66T5 is connected to a portion near the second end of the conductor layer 673. The through hole 66T6 is connected to a portion near the second end of the conductor layer 674.

The conductor layer 677 includes a first end and a second end located opposite to each other in the longitudinal direction of the conductor layer 677. The through hole 66T1a is connected to a portion near the first end of the conductor layer 677. The through hole 66T1b is connected to a portion near the second end of the conductor layer 677.

The conductor layer 678 includes a first end and a second end located opposite to each other in the longitudinal direction of the conductor layer 678. The through hole 66T2a is connected to a portion near the first end of the conductor layer 678. The through hole 66T2b is connected to a portion near the second end of the conductor layer 678.

The through holes 66T7a and 66T7b are respectively connected to through holes 67T7a and 67T7b shown in FIG. 8B.

FIG. 8C shows a patterned surface of the eighteenth dielectric layer 68. The through holes 67T3, 67T4, 67T7a, and 67T7b are respectively connected to through holes 68T3, 68T4, 68T7a, and 68T7b shown in FIG. 8C.

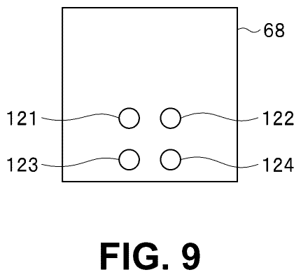

FIG. 9 shows a surface opposite to the patterned surface of the eighteenth dielectric layer 68. Hereinafter, the surface opposite to the patterned surface of the dielectric layer 68 is referred to as an electrode formation surface of the dielectric layer 68. The electrode formation surface of the dielectric layer 68 includes the electrodes 121, 122, 123, and 124 formed. The through holes 68T3, 68T4, 68T7a, and 68T7b are respectively connected to the electrodes 121, 122, 123, and 124.

The first body 50 includes the first to eighteenth dielectric layers 51 to 68 stacked such that the patterned surface of the first dielectric layer 51 serves as the second surface 50B of the first body 50 and the electrode formation surface of the eighteenth dielectric layer 68 serves as the first surface 50A of the first body 50.

Each of the plurality of through holes shown in FIGS. 5A to 8C is, with the first to eighteenth dielectric layers 51 to 68 stacked, connected to a conductor layer overlapping in the stacking direction T or to another through hole overlapping in the stacking direction T. Of the plurality of through holes shown in FIGS. 5A to 8C, a through hole located within an electrode or within a conductor layer is connected to the electrode or the conductor layer.

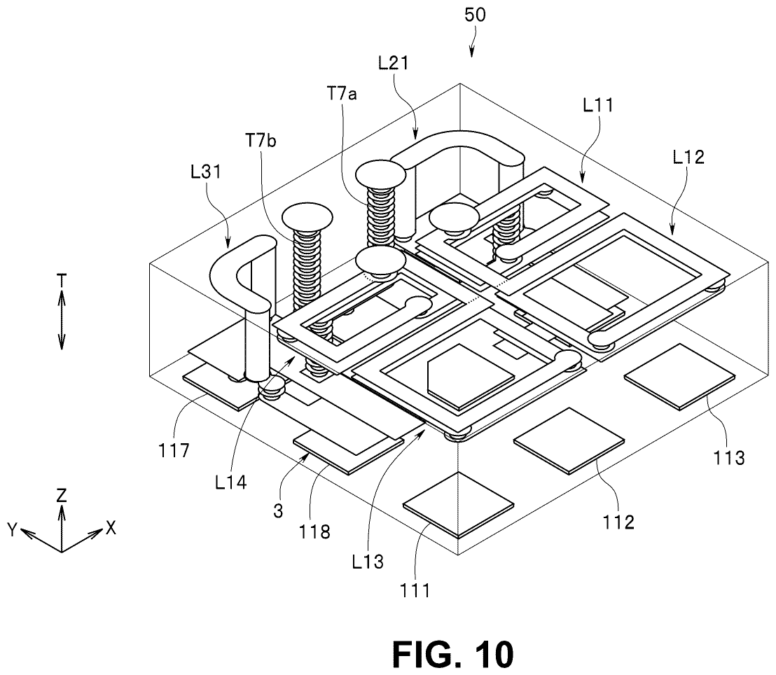

FIG. 10 shows inside of the first body 50 including the first to eighteenth dielectric layers 51 to 68 stacked. As shown in FIG. 10, the plurality of conductor layers and the plurality of through holes shown in FIGS. 5A to 9 are stacked inside the first body 50.

Correspondences between the components of the circuit of the filter device 1 shown in FIG. 1 and the internal components of the first body 50 shown in FIGS. 5A to 9 will now be described.

First, the filter circuit 10 will be described. The inductor L11 includes the inductor conductor layers 651, 661, and 671 and the through holes 65T3 and 66T3. The inductor L12 includes the inductor conductor layers 652, 662, and 672 and the through holes 65T4 and 66T4.

The inductor L13 includes the inductor conductor layers 653, 663, and 673 and the through holes 65T5 and 66T5. The inductor L14 includes the inductor conductor layers 654, 664, and 674 and the through holes 65T6 and 66T6.

The inductor L15 includes the through hole 51T7. The capacitor C11 includes the conductor layers 641, 652, and 653 and the dielectric layer 64 interposed between these conductor layers.

Next, the first low-pass filter 20 will be described. The inductor L21 includes the inductor conductor layer 677, the conductor layer 562, and the through holes 54T1a, 55T1a, 55T1b, 56T1a, 56T1b, 57T1a, 57T1b, 64T1a, 64T1b, 65T1a, 65T1b, 66T1a, and 66T1b.

The capacitor C21 includes the conductor layers 541 and 551 and the dielectric layer 54 interposed between these conductor layers. The capacitor C22 includes the conductor layers 542 and 552 and the dielectric layer 54 interposed between these conductor layers.

Next, the second low-pass filter 30 will be described. The inductor L31 includes the inductor conductor layer 678, the conductor layer 564, and the through holes 54T2a, 55T2a, 55T2b, 56T2a, 56T2b, 57T2a, 57T2b, 64T2a, 64T2b, 65T2a, 65T2b, 66T2a, and 66T2b.

The capacitor C31 includes the conductor layers 544 and 553 and the dielectric layer 54 interposed between these conductor layers. The capacitor C32 includes the conductor layers 543 and 554 and the dielectric layer 54 interposed between these conductor layers.

Next, the capacitors C1 to C4 will be described. The capacitor C1 includes the conductor layers 531 and 541 and the dielectric layer 53 interposed between these conductor layers. The capacitor C2 includes the conductor layers 551 and 561 and the dielectric layer 55 interposed between these conductor layers. The capacitor C3 includes the conductor layers 553 and 563 and the dielectric layer 55 interposed between these conductor layers. The capacitor C4 includes the conductor layers 532 and 544 and the dielectric layer 53 interposed between these conductor layers.

Next, features related to the acoustic wave elements 31 and 32 will be described. The one end of the acoustic wave element 31 is connected to the conductor layer 671 included in the inductor L11 and to the conductor layer 672 included in the inductor L12, via the conductor layer 675, the through holes 67T3 and 68T3, and the electrodes 121 and 81. The other end of the acoustic wave element 31 is connected to the through hole 51T7 included in the inductor L15, via the conductor layer 521, the through holes 52T7a, 53T7a, 54T7a, 55T7a, 56T7a, 57T7a, 64T7a, 65T7a, 66T7a, 67T7a, and 68T7a, and the electrodes 123 and 83.

Here, a pillar structure including a plurality of through holes connected in series is referred to as a pillar conductor. Such a pillar conductor extends in a direction parallel to the stacking direction T. A pillar conductor T7a shown in FIG. 10 includes the through holes 52T7a, 53T7a, 54T7a, 55T7a, 56T7a, 57T7a, 64T7a, 65T7a, 66T7a, 67T7a, and 68T7a. The other end of the acoustic wave element 31 is connected to the through hole 51T7 included in the inductor L15, via the conductor layer 521, the pillar conductor T7a, and the electrodes 123 and 83.

The one end of the acoustic wave element 32 is connected to the conductor layer 673 included in the inductor L13 and to the conductor layer 674 included in the inductor L14, via the conductor layer 676, the through holes 67T4 and 68T4, and the electrodes 122 and 82. A pillar conductor T7b shown in FIG. 10 includes the through holes 52T7b, 53T7b, 54T7b, 55T7b, 56T7b, 57T7b, 64T7b, 65T7b, 66T7b, 67T7b, and 68T7b. The other end of the acoustic wave element 32 is connected to the through hole 51T7 included in the inductor L15, via the conductor layer 521, the pillar conductor T7b, and the electrodes 124 and 84.

The operations and effects of the filter device 1 according to the example embodiment will now be described. In the example embodiment, the capacitors C1 and C2 are provided on the first path 5 connecting the first signal terminal 2 and the filter circuit 10 and the capacitors C3 and C4 are provided on the second path 6 connecting the second signal terminal 3 and the filter circuit 10. With this, according to the example embodiment, a signal of a low frequency passing through the first and second paths 5 and 6 is possible to be removed. As a result, according to the example embodiment, it is possible to prevent noise due to such a low frequency from being superimposed on a signal to be extracted by the filter device 1.

In the example embodiment, each of the acoustic wave elements 31 and 32 is electrically connected to the ground via the inductor L15. In particular in the example embodiment, each of the acoustic wave elements 31 and 32 is electrically connected to the ground only via a path via the inductor L15. Further, in the example embodiment, none of the acoustic wave elements 31 and 32 is electrically connected to the first or second signal terminal 2 or 3. In particular in the example embodiment, the first signal terminal 2 and second signal terminal 3 are not electrically connected to each other, and none of the electrode 114 corresponding to the first signal terminal 2 and the electrode 118 corresponding to the second signal terminal 3 is electrically connected to another electrode. With this, in the example embodiment, no current flows through the acoustic wave elements 31 or 32, even when static electricity is discharged near the filter device 1 and a voltage is applied to the electrodes 111 to 119.

As described above, the example embodiment enables reliability of the filter device 1 to be enhanced.

In the example embodiment, the first low-pass filter 20 is provided on the first path 5 and the second low-pass filter 30 is provided on the second path 6. When a signal is input into the filter circuit 10, besides the signal, the filter circuit 10 outputs harmonics in a frequency higher than that of the signal. According to the example embodiment, the first and second low-pass filters 20 and 30 enable such harmonics to be removed. With also this, the example embodiment enables reliability of the filter device 1 to be enhanced.

In the example embodiment, the capacitor C2 is connected in series to the inductor L11 of the filter circuit 10. The capacitor C2 and the inductor L11 are included in a series LC resonator. In general, a filter circuit using an acoustic wave element is suitable for achievement of pass attenuation characteristics that abruptly change in a frequency domain close to a passband. Such a filter circuit using an acoustic wave element, however, has an issue in that it is difficult to achieve a sufficient bandwidth. In contrast, according to the example embodiment, the series LC resonator including the capacitor C2 and the inductor L11 enables the passband to be widened.

Similarly, the capacitor C3 is connected in series to the inductor L14 of the filter circuit 10. The capacitor C3 and the inductor L14 are included in a series LC resonator. According to the example embodiment, the series LC resonator including the capacitor C3 and the inductor L14 enables the passband to be widened.

As described above, in the example embodiment, the capacitors C2 and C3 have a function of preventing noise due to a low frequency from being superimposed on a signal to be extracted by the filter device 1, a function of preventing a current due to static electricity from flowing through the acoustic wave elements 31 and 32, and a function of widening the passband.

Note that the disclosure is not limited to the foregoing example embodiment, and various modifications may be made thereto. For example, the filter device of the disclosure may be used not only for a band-pass filter but also for another filter device such as a low-pass filter or high-pass filter or for an electronic component including a plurality of resonators such as a branching filter that separates a plurality of signals in different frequency bands.

The second body 80 may include only one acoustic wave element or may include three or more acoustic wave elements. The second body 80 may include, in addition to the acoustic wave elements 31 and 32, any passive element such as a capacitor. In this case, such a passive element may be connected to the acoustic wave element 31 or 32. The second body 80 may include, instead of the acoustic wave elements 31 and 32 or in addition to the acoustic wave elements 31 and 32, any active element including a semiconductor such as a high frequency switch.

On each of the first and second paths 5 and 6, two or more low-pass filters may be provided. On each of the first and second paths 5 and 6, three or more capacitors may be provided.

As described above, a filter device according to one embodiment of the disclosure includes: a first body including a first element; a second body that is mounted on the first body and that includes a second element; a filter circuit including the first element and the second element; a first capacitor; and a second capacitor. The first body further includes a first signal terminal and a second signal terminal. The filter circuit is, in a circuit configuration, provided between the first signal terminal and the second signal terminal. The first capacitor is provided on a first path connecting the first signal terminal and the filter circuit. The second capacitor is provided on a second path connecting the second signal terminal and the filter circuit.

In the filter device according to one embodiment of the disclosure, the first capacitor and the second capacitor may be included in the first body.

In the filter device according to one embodiment of the disclosure, the filter circuit may be included in a high-pass filter. The second element may be connected to the ground.

The filter device according to one embodiment of the disclosure may further include a first low-pass filter provided on the first path. The first capacitor may be, in the circuit configuration, provided between the filter circuit and the first low-pass filter. The filter device according to one embodiment of the disclosure may further include a second low-pass filter provided on the second path. The second capacitor may be, in the circuit configuration, provided between the filter circuit and the second low-pass filter.

In the filter device according to one embodiment of the disclosure, the first element may be an inductor. The inductor may be connected in series to either one capacitor of the first capacitor or the second capacitor. The inductor and the one capacitor may be included in an LC resonator.

In the filter device according to one embodiment of the disclosure, the second element may be an acoustic wave element.

In the filter device of the disclosure, the first capacitor is provided on the first path connecting the first signal terminal and the filter circuit and the second capacitor is provided on the second path connecting the second signal terminal and the filter circuit. With this, according to the disclosure, it is possible to provide a filter device that enables reliability to be enhanced.

It is apparent that the disclosure can be carried out in various forms and modifications in the light of the foregoing descriptions. Accordingly, within the scope of the following claims and equivalents thereof, the disclosure can be carried out in forms other than the foregoing example embodiments.

1. A filter device comprising:
a first body including a first element;
a second body that is mounted on the first body and that includes a second element;
a filter circuit including the first element and the second element;
a first capacitor; and
a second capacitor, wherein
the first body further includes a first signal terminal and a second signal terminal,
the filter circuit is, in a circuit configuration, provided between the first signal terminal and the second signal terminal,
the first capacitor is provided on a first path connecting the first signal terminal and the filter circuit, and
the second capacitor is provided on a second path connecting the second signal terminal and the filter circuit.

2. The filter device according to claim 1, wherein the first capacitor and the second capacitor are included in the first body.

3. The filter device according to claim 1, wherein the filter circuit is included in a high-pass filter.

4. The filter device according to claim 3, wherein the second element is connected to a ground.

5. The filter device according to claim 1, further comprising a first low-pass filter provided on the first path.

6. The filter device according to claim 5, wherein the first capacitor is, in a circuit configuration, provided between the filter circuit and the first low-pass filter.

7. The filter device according to claim 5, further comprising a second low-pass filter provided on the second path.

8. The filter device according to claim 7, wherein the second capacitor is, in a circuit configuration, provided between the filter circuit and the second low-pass filter.

9. The filter device according to claim 1, wherein the first element is an inductor.

10. The filter device according to claim 9, wherein
the inductor is connected in series to either one capacitor of the first capacitor or the second capacitor, and
the inductor and the one capacitor are included in an LC resonator.

11. The filter device according to claim 1, wherein the second element is an acoustic wave element.
